(19) United States
(12) Patent Application Publication
(10) Pub. No.: US 2025/0197989 A1
(43) Pub. Date: Jun. 19, 2025

(54) SURFACE TREATMENT METHODS AND SYSTEMS, AND SURFACE-TREATED ARTICLES

(71) Applicant: Aspen Hybrid Technology Systems, Berthoud, CO (US)

(72) Inventors: Donald Lee Deptowicz, Berthoud, CO (US); Ronald Joseph Rudolph, Jensen Beach, FL (US); Gerald Thaddeus Mearini, Shaker Heights, OH (US)

(73) Assignee: Aspen Hybrid Technology Systems, Berthoud, CO (US)

(21) Appl. No.: 18/845,603

(22) PCT Filed: Mar. 13, 2023
(86) PCT No.: PCT/US23/15096

§ 371 Date: Sep. 10, 2024

Related U.S. Application Data
(60) Provisional application No. 63/318,973, filed on Mar. 11, 2022.

(51) Int. Cl. C23C 16/02; B08B 7/00; B23K 26/352; C23C 16/26

(52) U.S. Cl. CPC C23C 16/0263; B08B 7/0042; C23C 16/26; B23K 26/3576

(57) ABSTRACT

A surface treatment process includes laser ablation to remove surface contamination and coatings from a surface of a substrate, optionally treating the surface to improve uniformity, and applying a graphene-enhanced coating or a diamond-like carbon coating to the surface.

### BACKGROUND

This application claims the priority benefit of U.S. Provisional Application No. 63/318,973, filed Mar. 11, 2022, and titled “SURFACE TREATMENT SYSTEM,” which is incorporated by reference in its entirety.

### BACKGROUND

After the manufacturing and servicing of many complex components, the surfaces are contaminated with oxides, chlorides and other contaminants which are not possible to remove with traditional cleaning methods. It would be desirable to develop new systems and methods for treating surfaces.

### BRIEF DESCRIPTION

Disclosed, in some embodiments, are three-step surface treatment methods, systems for performing the methods, and articles formed by the methods. At the end of using the three-step process, the treated object includes (e.g., is encapsulated in) a diamond-like carbon coating. A first step uses an environmentally friendly laser ablation system to eliminate any remaining surface contamination that has accumulated during the manufacturing and packaging processes as well as any contaminant accumulation during service operation. This is a critical first step to maximize the effectiveness of the multiple step surface treatment process. Typically, any remaining surface contamination can cause an attack from the surface outward as well as inward and will result in a lower level of effectiveness. For the three-step method, the main purpose of a second step is to bring the component surface texture level down to a level that is compatible with the diamond-like carbon coating thickness (about 2 μm in some embodiments) inclusive of the bond layer. This is important because if any surface feature is higher than the diamond-like carbon coating thickness, it will protrude outside of the diamond-like carbon protective coating. This can result in a potential attack at the location where the diamond-like carbon coating has been penetrated and result in lower coating life. Another specific point for the second step is to ensure that, during the surface micro finishing process, the component surface does not become re-contaminated. The surface micro finishing process will not re-contaminate the surface. A third step is the application of the diamond-like carbon coating. The resulting coating may be about 2 μm thick. This diamond-like carbon coating chemistry may be modified from the original chemistry in order to maximize the adhesion to metallic objects with the addition of an adhesion coat.

Disclosed, in other embodiments, is a two-step surface treatment method. Systems for performing the method and articles formed by the method are also disclosed. The two-step surface treatment method may be useful if the article is not capable of fitting into the surface micro-finishing and/or diamond-like carbon coating equipment. The two-step method applies a graphene-enhanced coating to a surface of a substrate after laser ablation. A first step uses an environmentally friendly laser ablation system to eliminate any remaining surface contamination that has accumulated during the manufacturing and packaging processes as well as any contaminant accumulation during service operation. A second step applies a graphene-enhanced coating to the laser ablation cleaned substrate surface.

A surface treatment method in accordance with some embodiments of the present disclosure includes: laser ablating at least one surface of a substrate to remove surface contamination; micro-finishing the at least one surface to increase uniformity; and applying a diamond-like carbon coating to the at least one surface.

The diamond-like carbon coating may be applied via plasma-enhanced chemical vapor deposition.

In some embodiments, the diamond-like carbon coating has a thickness in a range of about 2 μm to about 15 μm, about 2 μm to about 7 μm, or about 2 μm to about 4 μm.

The substrate may contain one or more materials selected from the group consisting of: titanium, titanium alloys, stainless steel, iron, iron alloys, nickel, nickel alloys, aluminum, aluminum alloys, concrete, and plastic.

In some embodiments, the substrate contains at least one element selected from the group consisting of lithium, beryllium, sodium, magnesium, aluminum, potassium, calcium, scandium, titanium, vanadium, chromium, manganese, iron, cobalt, nickel, copper, zinc, gallium, Rb, strontium, yttrium, zirconium, niobium, molybdenum, technetium, ruthenium, rhodium, palladium, silver, cadmium, indium, tin, cesium, barium, lanthanum, cerium, praseodymium, neodymium, promethium, samarium, europium, gadolinium, terbium, dysprosium, holmium, erbium, thulium, ytterbium, lutetium, hafnium, tantalum, tungsten, rhenium, osmium, iridium, platinum, gold, thallium, lead, bismuth, polonium, francium, radium, actinium, thorium, protactinium, neptunium, plutonium, americium, curium, berkelium, californium, einsteinium, fermium, mendelevium, nobelium, lawrencium, rutherfordium, dubnium, seaborgium, bohrium, hassium, meitnerium, darmstadtium, roentgenium, copernicium, nihonium, flerovium, livermorium, boron, silicon, germanium, arsenic, antimony, and tellurium.

In particular embodiments, the diamond-like carbon coating is applied via plasma-enhanced chemical vapor deposition; the diamond-like carbon coating has a thickness in a range of about 2 μm to about 4 μm; and the substrate comprises one or more materials selected from the group consisting of: titanium, titanium alloys, stainless steel, iron, iron alloys, nickel, nickel alloys, aluminum, aluminum alloys, concrete, and plastic.

The laser ablation may be performed with a Q-switched, neodymium-doped yttrium aluminum garnet laser.

In some embodiments, the laser has a pulse frequency in a range of 10 KHz to 25 kHz.

Optionally, the method further includes applying an adhesion layer to the surface prior to the application of the diamond-like carbon coating.

In some embodiments, the adhesion layer comprises a carbide.

The carbide may be chromium carbide, titanium carbide, silicon carbide, or tungsten carbide.

In some embodiments, the substrate is encapsulated by the diamond-like carbon coating.

In particular embodiments, the diamond-like carbon coating is applied via plasma-enhanced chemical vapor deposition; the diamond-like carbon coating has a thickness in a range of about 2 μm to about 4 μm; the substrate comprises one or more materials selected from the group consisting of: titanium, titanium alloys, stainless steel, iron, iron alloys, nickel, nickel alloys, aluminum, aluminum alloys, concrete, and plastic; and wherein the method further includes: applying an adhesion layer (for example, a chromium carbide, titanium carbide, silicon carbide, or tungsten carbide adhesion layer) to the surface prior to the application of the diamond-like carbon coating.

A surface treatment method in accordance with other embodiments of the present disclosure includes: laser ablating at least one surface of a substrate to remove surface contamination; and applying a graphene-enhanced coating to the at least one surface.

In some embodiments, the graphene-enhanced coating contains about 0.001 wt % to about 0.5 wt % graphene.

The graphene-enhanced coating may include an epoxy.

In some embodiments, the epoxy is a multi-component epoxy.

The graphene-enhanced coating may be applied via spray coating.

In some embodiments, the graphene-enhanced coating has a thickness in a range of about 2 μm to about 15 μm, about 2 μm to about 7 μm, or about 2 μm to about 4 μm.

The substrate may contain one or more materials selected from the group consisting of: titanium, titanium alloys, stainless steel, iron, iron alloys, nickel, nickel alloys, aluminum, aluminum alloys, concrete, and plastic.

In some embodiments, the substrate contains at least one element selected from the group consisting of lithium, beryllium, sodium, magnesium, aluminum, potassium, calcium, scandium, titanium, vanadium, chromium, manganese, iron, cobalt, nickel, copper, zinc, gallium, Rb, strontium, yttrium, zirconium, niobium, molybdenum, technetium, ruthenium, rhodium, palladium, silver, cadmium, indium, tin, cesium, barium, lanthanum, cerium, praseodymium, neodymium, promethium, samarium, europium, gadolinium, terbium, dysprosium, holmium, erbium, thulium, ytterbium, lutetium, hafnium, tantalum, tungsten, rhenium, osmium, iridium, platinum, gold, thallium, lead, bismuth, polonium, francium, radium, actinium, thorium, protactinium, neptunium, plutonium, americium, curium, berkelium, californium, einsteinium, fermium, mendelevium, nobelium, lawrencium, rutherfordium, dubnium, seaborgium, bohrium, hassium, meitnerium, darmstadtium, roentgenium, copernicium, nihonium, flerovium, livermorium, boron, silicon, germanium, arsenic, antimony, and tellurium.

In particular embodiments, the graphene-enhanced coating comprises an epoxy and about 0.001 wt % to about 0.5 wt % graphene; the diamond-like carbon coating has a thickness in a range of about 2 μm to about 4 μm; and the substrate comprises one or more materials selected from the group consisting of: titanium, titanium alloys, stainless steel, iron, iron alloys, nickel, nickel alloys, aluminum, aluminum alloys, concrete, and plastic.

The substrate may be encapsulated in the graphene-enhanced coating.

These and other non-limiting characteristics are more particularly described below.

### BRIEF DESCRIPTION OF THE DRAWINGS

The following is a brief description of the drawings, which are presented for the purposes of illustrating the exemplary embodiments disclosed herein and not for the purposes of limiting the same.

FIG. 1 is a flow chart illustrating a first surface treatment method in accordance with some non-limiting embodiments of the present disclosure.

FIG. 2 is a side, cross-sectional view of an article produced by the method of FIG. 1.

FIG. 3 is a flow chart illustrating a second surface treatment method in accordance with some non-limiting embodiments of the present disclosure.

FIG. 4 is a side, cross-sectional view of an article produced by the method of FIG. 3.

### DETAILED DESCRIPTION

The present disclosure may be understood more readily by reference to the following detailed description of desired embodiments included therein. In the following specification and the claims which follow, reference will be made to a number of terms which shall be defined to have the following meanings.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent can be used in practice or testing of the present disclosure. All publications, patent applications, patents, and other references mentioned herein are incorporated by reference in their entirety. The materials, methods, and articles disclosed herein are illustrative only and not intended to be limiting.

The singular forms “a,” “an,” and “the” include plural referents unless the context clearly dictates otherwise.

As used in the specification and in the claims, the term “comprising” may include the embodiments “consisting of” and “consisting essentially of.” The terms “comprise(s),” “include(s),” “having,” “has,” “can,” “contain(s),” and variants thereof, as used herein, are intended to be open-ended transitional phrases that require the presence of the named ingredients/steps and permit the presence of other ingredients/steps. However, such description should be construed as also describing compositions, mixtures, or processes as “consisting of” and “consisting essentially of” the enumerated ingredients/steps, which allows the presence of only the named ingredients/steps, along with any impurities that might result therefrom, and excludes other ingredients/steps.

The surface treatment methods of the present disclosure lead to increased system performance, durability, reliability, and reduced maintenance on numerous components, machinery and tooling over a wide range of industries. This includes a biocompatible system for use with living tissue.

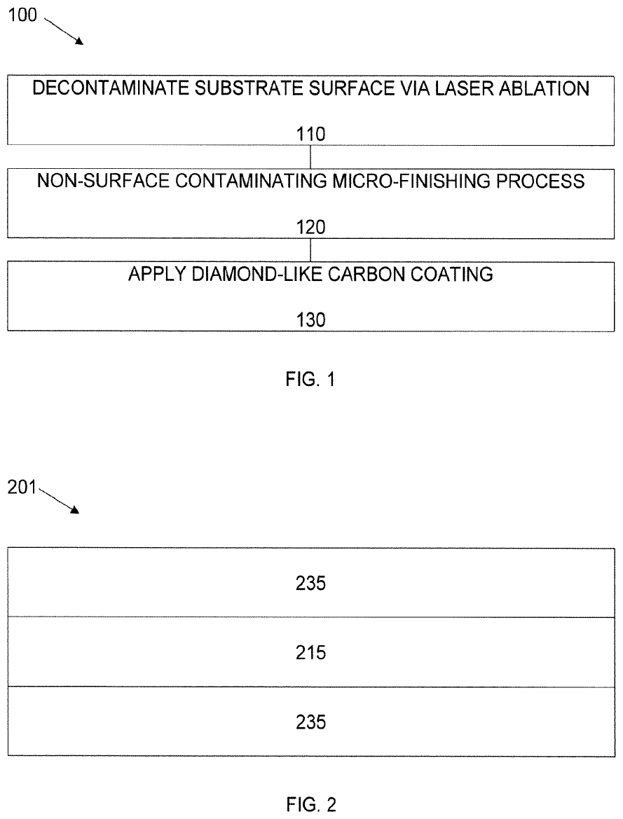

FIG. 1 illustrates a three-step surface treatment method 100 in accordance with some embodiments of the present disclosure. The method 100 includes decontaminating a substrate surface via laser ablation 110, non-surface contaminating micro-finishing 120, and applying a diamond-like carbon coating 130.

Step 110 of FIG. 1 is a surface cleaning step which uses an environmentally friendly laser ablation system to eliminate any surface contamination that has accumulated during the manufacturing and packaging processes as well as any contaminant accumulation during service operation. This process step will eliminate any possibility of chemical migration attack from the surface outward if a surface coating is utilized. It is important to ensure that during the laser ablation process no substrate surface micro melting or cellular tissue damage occurs as this would have a negative impact on the strength of the object. Therefore, optimization of the laser ablation system process parameters is important. Care must be taken to ensure that no surface micro melting or cellular damage (living organisms) occurs during the laser ablation process as that would likely negatively impact the durability of the object being coated. Selection of the laser ablation system is important to ensure that during the laser ablation process no substrate surface micro melting occurs as this would likely have a negative impact on the strength of the object being cleaned. In some non-limiting embodiments, laser ablation is performed using a q-switched, neodymium-doped yttrium aluminum garnet laser. The laser may have a pulse frequency in a range of about 10 kHz to about 25 KHz.

Step 120 of FIG. 1 is a surface roughness reduction step which addresses the issue of specific outlying machining defects that are not typically captured using the Ra surface roughness measurement system. It is important to not have any surface features protruding out of the diamond-like carbon coating system, since any upper surface protrusions can allow an attack at the coating system substrate interface. In addition to a uniform level of texture, the finishing process should not provide an opportunity to re-contaminate the surface with any abrasive medium or chemicals (liquid or gaseous) as many surface finishing processes often do. In order to optimize the durability of the diamond-like carbon coating, the surface roughness must be very uniform, so the measurement technique must take into account these high peaks to ensure that none of them penetrate outside of the diamond-like carbon coating. Therefore, a surface measurement system similar to Rz, Rpk, etc. where the highest surface features are accounted for is required. An additional requirement for step 120 is to not re-contaminate the surface after step 110 eliminated all surface contamination.

Valleys are not even captured when measuring surface roughness using some traditional industry techniques. For the space shuttle program, surface roughness may need to be reduced down to the angstrom level (1 μm=10,000 Å). It is like a mirror surface finish when at those levels (e.g., 1,000 Å). A machined surface may have a thickness of about 33 micro inches and that would be about 8,400 Å.

The surface after surface roughness reduction may not have any peaks exceeding the thickness of the subsequently applied diamond-like carbon coating. In some embodiments, there may not be any peaks within 90%, 80%, 70%, 60%, 50%, 40%, 30%, 20%, or 10% of the thickness of the coating.

In particular embodiments, the tallest peaks (e.g., Rpk) are at most 0.5 μm, 0.3 μm, or 0.2 μm.

In step 130 of FIG. 1, an impermeable diamond-like carbon coating is applied. Step 130 of the method applies an approximately 2-μm thick diamond-like carbon coating. The coating may be applied via plasma-enhanced chemical vapor deposition or electrostatically. This specific diamond-like carbon coating chemistry has been modified from the original chemistry in order to maximize the adhesion to metallic objects since the original chemistry was applied to nonmetallic surfaces. This is a vacuum deposited amorphous carbon film is well known for its wear-resistant and tribological properties. This will encase the component in an almost impervious layer of protection that virtually eliminates adherence of foulants to the surface. diamond-like carbon coatings have a very low coefficient of friction (more than 10× lower than Teflon), are very hard and exhibit a hydrophobic behavior, i.e., water will not wet the surface. This unique combination of technologies then creates an omniphobic protective environment that is compatible with both metallic and non-metallic parts as well as being biocompatible with living tissue. Prior to applying the diamond-like carbon coating, an adhesion layer (e.g., a hybrid adhesion layer) may be applied to promote the adhesion of the diamond-like carbon coating to the substrate. The adhesion layer may be applied via the same deposition equipment (e.g., PECVD) as the diamond-like carbon coating. In some non-limiting embodiments, the adhesion layer contains a carbide (e.g., a metal carbide) or a metal that reacts to form a carbide. Some suitable examples include chromium, titanium, silicon, tungsten, chromium carbide, titanium carbide, silicon carbide, tungsten carbide, and combinations thereof. Alternatively, the diamond-like carbon coating may be applied directly to the substrate without the use of an adhesion layer.

FIG. 2 illustrates a non-limiting embodiment of an article 201 formed by the process of FIG. 1. The article 201 includes a substrate 215 and a diamond-like carbon coating 235. Although the depicted embodiment includes the coating 235 on both the top and bottom surfaces of the substrate 215, it should be understood that alternatively the coating may be applied on only one surface. Moreover, it is also contemplated that the substrate 215 may be completely encapsulated by the coating (i.e., on the left side, the right side, the front side, and the rear side). Any number of surfaces may be coated. Additionally, although the depiction of FIG. 2 shows a continuous coating on the entire top and bottom surfaces of the substrate 215, it should be understood that the coating may also be discontinuous and/or may cover only a portion of the surface of the substrate 215.

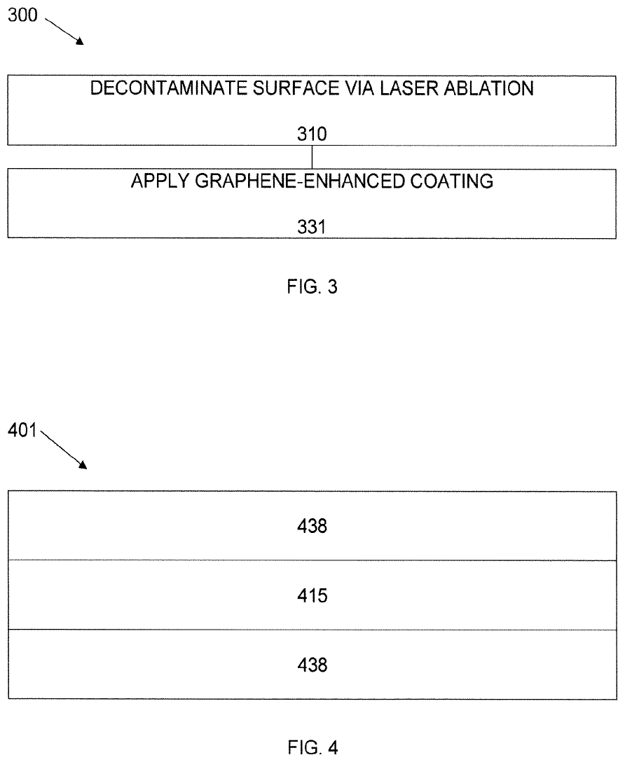

FIG. 3 illustrates a two-step surface treatment method in accordance with other embodiments of the present disclosure. Step 310 of FIG. 1 is a surface cleaning step similar to Step 110 of FIG. 1. Step 310 uses an environmentally friendly laser ablation system to eliminate any remaining surface contamination that has accumulated during the manufacturing and packaging processes as well as any contaminant accumulation during service operation. This process step will eliminate any possibility of chemical migration attack from the surface outward if a surface coating is utilized. It is important to ensure that during the laser ablation process no substrate surface micro melting or cellular tissue damage occurs as this would have a negative impact on the strength of the object. Therefore, optimization of the laser ablation system process parameters is important. The second step depends on the size of the object that the method will be applied to. Care must be taken to ensure that no surface micro melting occurs during the laser ablation process as that would likely negatively impact the durability of the object being coated. Selection of the laser ablation system is important to ensure that during the laser ablation process no substrate surface micro melting occurs as this would likely have a negative impact on the strength of the object being cleaned. In some non-limiting embodiments, laser ablation is performed using a q-switched, neodymium-doped yttrium aluminum garnet laser. The laser may have a pulse frequency in a range of about 10 kHz to about 25 kHz.

Step 331 of FIG. 3 is a graphene-enhanced coating step. The graphene-enhanced coating is matched to the substrate. Graphene-enhanced coatings have shown to have superior performance compared to those without graphene. In addition, applying the graphene-enhanced coating over the laser ablation cleaned substrate surface, where all impurities are removed, will provide even better coating adhesion, anti-fouling, and corrosion protection. In non-limiting embodiments, the graphene-enhanced coating is applied via spraying and/or manually.

FIG. 4 illustrates a non-limiting embodiment of an article 401 formed by the process of FIG. 3. The article 401 includes a substrate 415 and a diamond-like carbon coating 438. Although the depicted embodiment includes the coating 438 on both the top and bottom surfaces of the substrate 415, it should be understood that alternatively the coating may be applied on only one surface. Moreover, it is also contemplated that the substrate 415 may be completely encapsulated by the coating (i.e., on the left side, the right side, the front side, and the rear side). Any number of surfaces may be coated. Additionally, although the depiction of FIG. 4 shows a continuous coating on the entire top and bottom surfaces of the substrate 415, it should be understood that the coating may also be discontinuous and/or may cover only a portion of the surface of the substrate 415.

Laser ablation is used in the methods of FIGS. 1 and 3 in order to completely eliminate any surface contamination that is so important in order to eliminate of any potential coating attack coming from underneath either the diamond-like carbon or graphene-enhanced coatings. The second step depends on the size of the object that the treatment method will be applied to. For the method of FIG. 1, step 220 addresses the issue of specific outlying machining defects that are not typically captured using the Ra, surface roughness measurement system. In order to optimize the durability of the diamond-like carbon coating, the surface roughness must be very uniform, so the measurement technique must take into account these high peaks to ensure that none of them penetrate outside of the diamond-like carbon coating. Therefore, a surface measurement system similar to R_{z}, Rₚₖ, etc. where the highest surface features are accounted for is required. An additional requirement for this step 120 is to not re-contaminate the surface after step 110 eliminated all surface contamination. For large projects that do not fit into the existing surface micro-finishing and/or diamond-like carbon equipment, the two-step method of FIG. 3 may be used. Step 331 applies a graphene-enhanced coating that is specifically matched to the substrate it is being applied to. Step 130 of the method of FIG. 1 is the application of the approximately 2-μm thick diamond-like carbon coating using a PECVD process. The irradiance (i.e., spot brightness) and fluence (i.e., average power delivered across the laser spot) may be optimized.

The laser ablation process leaves the surface contamination free. The laser ablation process is environmentally friendly compared to other surface cleaning processes. The surface finishing process is abrasive media free and leaves the object's surface contamination free diamond-like carbon coating chemistry has a functionally graded hybrid adhesion layer to improve performance on metallic and non-metallic objects. The Surface Treatment System results in a surface that is omniphobic, meaning that nothing adheres to it. The treatment methods provide a highly corrosive and environmental resistant protective layer.

The method of FIG. 1 combines a multi-step system that addresses these aforementioned issues starting from ensuring component surface cleanliness, surface micro-finishing (when applying diamond-like carbon) to ensure the compatibility of the surface topology to the application of a very thin diamond-like carbon coating (when using surface micro-finishing) to create an omniphobic system that is both wear resistant and frictionless. Elimination of chemical and solid media cleaning reduces the probability of intergranular attack (metals) and layer delamination (composite materials). For those projects that exceed the size requirements of the surface micro-finishing and diamond-like carbon equipment an alternative option (FIG. 3) is to apply a graphene-enhanced coating that is specifically selected for the substrate being coated. Graphene-enhanced coatings have shown to have superior performance when compared to the equivalent standard coating/protection systems. Coupled with the Laser Ablation cleaned substrate surface, the graphene-enhanced coating will provide superior adhesion and durability. Another advantage of the treatment method with the diamond-like carbon coating over traditional coating systems is that the very thin application thickness will not impact component form, fit, or function as other thicker coating systems will.

Non-limiting examples of substrate materials for use as the substrate 215, 415 include titanium, titanium alloys, stainless steel, iron, iron alloys, nickel, nickel alloys, aluminum, aluminum alloys, and non-metallics (e.g., concretes, plastics, and composite materials). In some embodiments, the substrate contains elemental metal, an elemental metalloid, or an alloy containing one or more metal elements and/or one or more metalloid elements. Non-limiting examples of such elements include lithium, beryllium, sodium, magnesium, aluminum, potassium, calcium, scandium, titanium, vanadium, chromium, manganese, iron, cobalt, nickel, copper, zinc, gallium, Rb, strontium, yttrium, zirconium, niobium, molybdenum, technetium, ruthenium, rhodium, palladium, silver, cadmium, indium, tin, cesium, barium, lanthanum, cerium, praseodymium, neodymium, promethium, samarium, europium, gadolinium, terbium, dysprosium, holmium, erbium, thulium, ytterbium, lutetium, hafnium, tantalum, tungsten, rhenium, osmium, iridium, platinum, gold, thallium, lead, bismuth, polonium, francium, radium, actinium, thorium, protactinium, neptunium, plutonium, americium, curium, berkelium, californium, einsteinium, fermium, mendelevium, nobelium, lawrencium, rutherfordium, dubnium, seaborgium, bohrium, hassium, meitnerium, darmstadtium, roentgenium, copernicium, nihonium, flerovium, livermorium, boron, silicon, germanium, arsenic, antimony, and tellurium.

The diamond-like carbon or graphene coating may have a thickness in the range of about 2 μm to about 15 μm, including from about 2 μm to about 7 μm and about 2 μm to about 4 μm. As coatings get thicker, they become more brittle. It should also be understood that the above values may be modified by ±0.5 μm, ±0.3 μm, or ±0.2 μm.

The graphene-enhanced coating may contain between about 0.001 wt % to about 0.5 wt %, including from about 0.01 wt % to about 0.5 wt %, about 0.1 wt % to about 0.5 wt %, about 0.01 wt % to about 0.4 wt %, about 0.01 wt % to about 0.3 wt %, about 0.01 wt % to about 0.2 wt %, about 0.01 wt % to about 0.1 wt %, about 0.1 wt % to about 0.4 wt %, about 0.1 wt % to about 0.3 wt %, or about 0.1 wt % to about 0.2 wt %.

The graphene-enhanced coating may be an epoxy coating (e.g., a multi-step epoxy coating).

The graphene-enhanced coating may have a thickness in a range of 0.002″ to about 0.25″, about 0.04″ to about 0.125″, or about 0.002″ to about 0.001″. It should be understood that the above values may be modified by +0.001″, +0.005″, +0.010″, or 0.020″.

Non-limiting examples of suitable applications include parts for military aircraft, commercial airlines, airplane manufacturers, aircraft engine manufacturers, land-based gas turbine power plants, military and commercial marine applications, wind turbines, machining tool designers, automobile industry, gas and oil drilling and pumping equipment, maritime and recreational boat builders and Marine MRO service companies, medical applications, and space vehicles (micro-organism adherence), etc.

Potential benefits include reduced gas turbine/surface fouling for improved efficiency, fuel consumption, and hot section and gear box component lives for increased readiness and reduced maintenance costs and down time; reduced wear/frictional losses and increased durability of manufacturing tooling, injection systems, oil and gas drilling and pumping equipment, medical implants, etc.; high precision gears for watches, clocks, etc. will virtually never need to be repaired. The methods may improve corrosion resistance significantly and increase the lives of numerous marine applications such as but not limited to, marine engine shafts, bow thrusters, improved anti-fouling and corrosion protection for the maritime industry, etc. The methods may reduce frictional losses on any rotating equipment for improved performance and durability.

Diamond-like carbon is an amorphous carbon material that displays some of the typical properties of diamond. The diamond-like carbon of the present disclosure hydrogenated or hydrogen-free. Optionally, the hydrogen fee diamond-like carbon is modified with a metal. Optionally, the hydrogenated diamond-like carbon is modified with a metal or a non-metal.

The diamond-like carbon coating may be a hydrogen-free amorphous carbon film, a tetrahedral hydrogen-free amorphous carbon film, a metal-containing hydrogen-free amorphous carbon film, a hydrogenated amorphous carbon film, a tetrahedral hydrogenated amorphous carbon film, a metal-containing hydrogenated amorphous carbon film, or a modified hydrogenated amorphous carbon film.

In particular embodiments, the diamond-like carbon coating contains hydrogenated amorphous carbon and is used in combination with at least one adhesion layer containing one or more of germanium, silicon, and carbon.

The adhesion layer(s) may contain all of germanium, silicon, and carbon.

In some embodiments, the adhesion layer(s) contain germanium carbide and/or silicon carbide.

It will be appreciated that variants of the above-disclosed and other features and functions, or alternatives thereof, may be combined into many other different systems or applications. Various presently unforeseen or unanticipated alternatives, modifications, variations, or improvements therein may be subsequently made by those skilled in the art which are also intended to be encompassed by the following claims.

1. A surface treatment method comprising:
laser ablating at least one surface of a substrate to remove surface contamination;
micro-finishing the at least one surface to increase uniformity; and
applying a diamond-like carbon coating to the at least one surface.

2. The surface treatment method of claim 1, wherein the diamond-like carbon coating is applied via plasma-enhanced chemical vapor deposition; and/or wherein the diamond-like carbon coating has a thickness in a range of about 2 μm to about 15 μm.

3-5. (canceled)

6. The surface treatment method of claim 1, wherein the substrate comprises one or more materials selected from the group consisting of: titanium, titanium alloys, stainless steel, iron, iron alloys, nickel, nickel alloys, aluminum, aluminum alloys, concrete, and plastic.

7. (canceled)

8. The surface treatment method of claim 1, wherein the laser ablation is performed with a Q-switched, neodymium-doped yttrium aluminum garnet laser.

9. The surface treatment method of claim 8, wherein the laser has a pulse frequency in a range of 10 KHz to 25 KHz.

10. The surface treatment method of claim 1, further comprising:
applying an adhesion layer to the surface prior to the application of the diamond-like carbon coating.

11. The surface treatment method of claim 10, wherein the adhesion layer comprises a carbide.

12-16. (canceled)

17. The surface treatment method of claim 1, wherein the diamond-like carbon coating comprises hydrogenated amorphous carbon.

18. The surface treatment method of claim 17, wherein the method further comprises:
applying an adhesion layer to the surface prior to the application of the diamondlike carbon coating.

19. The method of claim 18, wherein the adhesion layer comprises at least one element selected from the group consisting of germanium, silicon, and carbon.

20. The method of claim 18, wherein the adhesion layer comprises germanium, silicon, and carbon.

21. The method of claim 18, wherein the adhesion layer comprises silicon carbide.

22. The method of claim 18, wherein the adhesion layer comprises germanium carbide.

23. The method of claim 18, wherein the adhesion layer comprises silicon carbide and germanium carbide.

24. (canceled)

25. A surface treatment method comprising:
laser ablating at least one surface of a substrate to remove surface contamination; and
applying a graphene-enhanced coating to the at least one surface.

26. The surface treatment method of claim 25, wherein the graphene-enhanced coating comprises about 0.001 wt % to about 0.5 wt % graphene.

27. The surface treatment method of claim 25, wherein the graphene-enhanced coating comprises an epoxy.

28. The surface treatment method of claim 27, wherein the epoxy is a multicomponent epoxy.

29. The surface treatment method of claim 25, wherein the graphene-enhanced coating is applied via spray coating and/or wherein the graphene-enhanced coating has a thickness in a range of about 2 μm to about 15 μm.

30-32. (canceled)

33. The surface treatment method of claim 25, wherein the substrate comprises one or more materials selected from the group consisting of: titanium, titanium alloys, stainless steel, iron, iron alloys, nickel, nickel alloys, aluminum, aluminum alloys, concrete, and plastic.

34-37. (canceled)
